(19) United States
(12) Patent Application Publication
(10) Pub. No.: US 2023/0178694 A1
(43) Pub. Date: Jun. 8, 2023

(54) LAYERED LIGHT EMITTING ELEMENT AND DISPLAY DEVICE USING THE SAME

(71) Applicant: LG ELECTRONICS INC., Seoul (KR)

(72) Inventors: Sangyeol LEE, Seoul (KR); Sangtae PARK, Seoul (KR); Chansung JEONG, Seoul (KR); Jeongtak OH, Seoul (KR); Youngkyu JEONG, Seoul (KR); Sunwoo PARK, Seoul (KR)

(73) Assignee: LG ELECTRONICS INC., Seoul (KR)

(21) Appl. No.: 18/061,318

(22) Filed: Dec. 2, 2022

(30) Foreign Application Priority Data
Dec. 3, 2021 (KR) 10-2021-0171554
Dec. 15, 2021 (KR) 10-2021-0179325
Oct. 4, 2022 (KR) 10-2022-0126612

(51) Int. Cl. H01L 33/54; H01L 25/16; H01L 33/60; H01L 23/00

(52) U.S. Cl. CPC H01L 33/54; H01L 24/08; H01L 25/167; H01L 33/60; H01L 33/56

(57) ABSTRACT

The present disclosure is applicable to the display device relevant technical field, and, for example, relates to a layered light emitting diode and display device using the same. Disclosed is a layered light emitting element, including a semiconductor structure having a multitude of semiconductor layers stacked to emit lights of first to third colors, respectively, first and second electrodes electrically connected to one side and the other side of the semiconductor layer on a first face of the semiconductor structure, respectively, a support layer located on a second face of the semiconductor structure, and a reflective layer located to surround a lateral side of the semiconductor structure at least.

### CROSS REFERENCE TO RELATED APPLICATIONS

Pursuant to 35 U.S.C. § 119(a), this application claims the benefit of earlier filing date and right of priority to Korean Patent Application Nos. 10-2021-0171554, filed on Dec. 3, 2021, 10-2021-0179325, filed on Dec. 15, 2021, and 10-2022-0126612, filed on Oct. 4, 2022, the contents of which are all hereby incorporated by reference herein in their entireties.

### BACKGROUND OF THE DISCLOSURE

### Field of the Disclosure

The present disclosure is applicable to the display device relevant technical field, and, for example, relates to a layered Light Emitting Diode (LED) and display device using the same.

### Discussion of the Related Art

Recently, in the field of display technology, display devices having excellent features such as thinness, flexibility and the like have been developed. Currently, major displays that have been commercialized are represented by Liquid Crystal Display (LCD) and Organic Light Emitting Diodes (OLED).

Meanwhile, a Light Emitting Diode (LED) is a semiconductor light emitting element well known for converting current into light, and has been used as a light source for display images of an electronic device along with GaP:N series green LEDs since 1962 when red LEDs using GaAsP compound semiconductors were commercialized.

Recently, such a Light Emitting Diode (LED) is gradually miniaturized and fabricated as a micrometer-sized LED and used as a pixel of a display device.

Such LED technology shows characteristics of low power, high luminance, and high reliability compared to other display devices/panels, and can be applied to flexible devices. Therefore, it has been actively studied in research institutes and companies in recent years.

When such an LED is used as a pixel, light traveling to a lateral side of the LED may be trapped inside a display device or a display module. This may act as a factor that degrades performance in terms of light extraction efficiency.

In addition, the light traveling to the lateral side of the LED may generate a bright line at the boundary between display modules through internal total reflection, which may act as a defect from the display perspective.

Meanwhile, in order to overcome this, the contrast may decrease when the content of the scattering agent in a scattering layer is increased. That is, the increase in the scattering agent has a trade-off relationship in which the blackness decreases in the display device. In addition, this may cause performance degradation due to an increase in a diffusive reflection property at the top of the LED.

Therefore, there is a need for a method for solving this problem.

### SUMMARY OF THE DISCLOSURE

Accordingly, embodiments of the present disclosure are directed to a layered light emitting diode and display device using the same that substantially obviate one or more problems due to limitations and disadvantages of the related art.

One technical task of the present disclosure is to provide a display device using a light emitting element, and more particularly, a layered light emitting element and display device using the same, which may increase light efficiency by allowing light traveling to a lateral side of the light emitting element to travel to a front side.

Another technical task of the present disclosure is to provide a layered light emitting element and display device using the same, which may uniformize viewing angles due to different light distribution properties among red, green, and blue.

When a display device has a structure of modules connected to each other, further technical task of the present disclosure is to provide a layered light emitting element and display device using the same, which may improve the effect of bright line occurrence between the modules.

Additional advantages, objects, and features of the disclosure will be set forth in the disclosure herein as well as the accompanying drawings. Such aspects may also be appreciated by those skilled in the art based on the disclosure herein.

To achieve these objects and other advantages and in accordance with the purpose of the disclosure, as embodied and broadly described herein, a layered light emitting element may include a semiconductor structure having a multitude of semiconductor layers stacked to emit lights of first to third colors, respectively, first and second electrodes electrically connected to one side and the other side of the semiconductor layer on a first face of the semiconductor structure, respectively, a support layer located on a second face of the semiconductor structure, and a reflective layer located to surround a lateral side of the semiconductor structure at least.

In one embodiment, the reflective layer may be located to further surround a lateral side of the support layer.

In one embodiment, the reflective layer may have a predetermined thickness on the lateral side of the semiconductor structure.

In one embodiment, the reflective layer may include a transparent resin layer and reflective particles dispersed in the transparent resin layer.

In one embodiment, a refractive index of the reflective particles may be different from a refractive index of the transparent resin layer.

In one embodiment, the reflective particles may include at least one of silicon oxide, titanium oxide, or zirconium oxide.

A thickness of the reflective layer may be set to have a reflectivity of 90% or more by the transparent resin layer and the reflective particles.

In one embodiment, the transparent resin layer may include at least one material of silicon, epoxy, or urethane.

In one embodiment, the layered light emitting element may further include an extension pad connected to each of the first electrode and the second electrode.

In one embodiment, an outer side end of the extension pad may be in contact with the reflective layer.

In one embodiment, the reflective layer may be further located on a top side of the support layer.

In another aspect of the present disclosure, as embodied and broadly described herein, a display device may include a wiring substrate, a light emitting element disposed on the wiring substrate to form an individual pixel and having a semiconductor structure including a multitude of semiconductor layers stacked to emit lights of first to third colors, respectively, and a reflective layer filling a space between the light emitting elements, the reflective layer including a transparent resin layer and particles dispersed in the transparent resin layer.

In one embodiment, the reflective layer may have a hang structure between neighboring light emitting elements.

In one embodiment, a height of the hang structure may be greater than a half of a height of the light emitting element.

In one embodiment, a maximum height of the reflective layer may correspond to a greatest height of the light emitting element.

Accordingly, the present disclosure provides the following effects and/or advantages.

First, according to one embodiment of the present disclosure, it is possible to increase light efficiency by allowing light traveling to a lateral side of a light emitting element to travel to a front side.

In addition, it is possible to uniformize the viewing angles due to different light distribution properties among red, green, and blue.

In addition, when display devices have a module structure in a manner of being connected to each other, it is possible to improve the phenomenon of bright line occurrence between modules.

In addition, there is an effect of substantially extending the size of a light emitting element.

Furthermore, according to another embodiment of the present disclosure, there are additional effects not mentioned herein. Those of ordinary skill in the art may understand it through the full text of the specification and drawings.

### BRIEF DESCRIPTION OF THE DRAWINGS

The present invention will become more fully understood from the detailed description given herein below and the accompanying drawings, which are given by illustration only, and thus are not limitative of the present invention, and wherein:

FIG. 1 is a cross-sectional diagram showing pixel regions of a display device using light emitting elements according to one embodiment of the present disclosure;

FIG. 2A is a cross-sectional diagram showing a unit pixel region of a display device using light emitting elements according to one embodiment of the present disclosure;

FIG. 2B is an enlarged diagram showing a display device using light emitting elements according to one embodiment of the present disclosure;

FIG. 3 is a cross-sectional diagram showing a light emitting element of a display device using light emitting elements according to one embodiment of the present disclosure;

FIG. 4 is a diagram showing a modified example of the light emitting element of FIG. 3;

FIG. 5 is a cross-sectional diagram showing a light emitting element of a display device using light emitting elements according to another embodiment of the present disclosure;

FIG. 6 is a diagram showing a modified example of the light emitting element of FIG. 5;

FIG. 7 is a cross-sectional diagram showing a light emitting element of a display device using light emitting elements according to another embodiment of the present disclosure;

FIGS. 8 to 11 are schematic cross-sectional diagrams showing a process for fabricating a light emitting element of a display device using light emitting elements according to one embodiment of the present disclosure;

FIGS. 12 to 15 are schematic cross-sectional diagrams showing a process for fabricating a light emitting element of a display device using light emitting elements according to another embodiment of the present disclosure; and

FIG. 16 is a diagram of pictures showing light emitting states by a light emitting element of a display device using light emitting elements according to another embodiment of the present disclosure.

### DETAILED DESCRIPTION OF THE DISCLOSURE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described herein is a concept including all display devices that display information with a unit pixel or a set of unit pixels. Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light emitting element mentioned in this specification is a concept including an LED, a micro LED, and the like, and may be used interchangeably therewith.

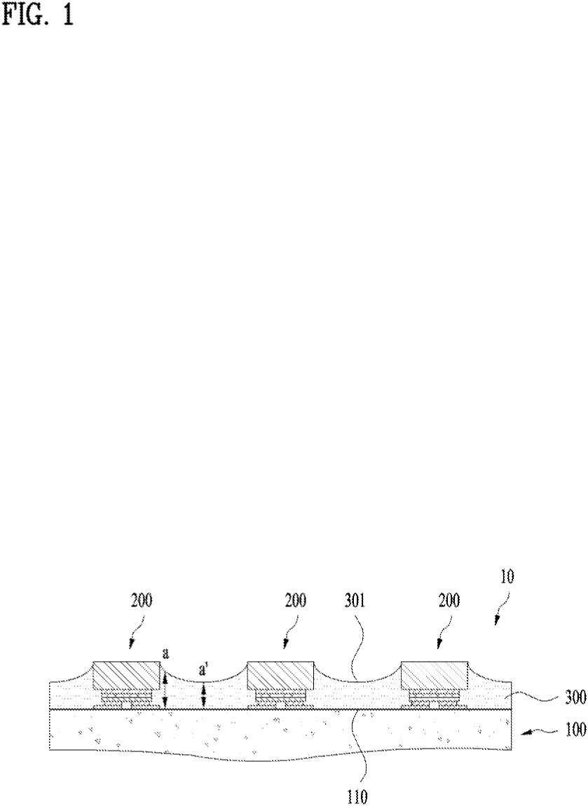

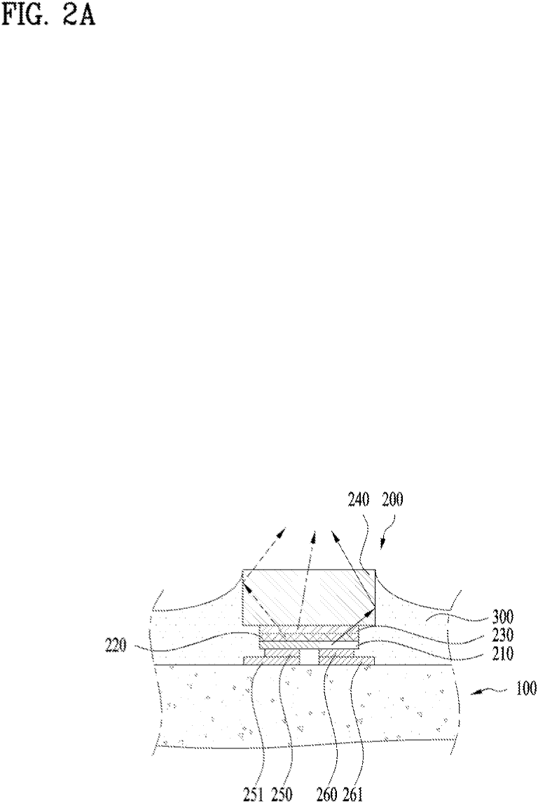

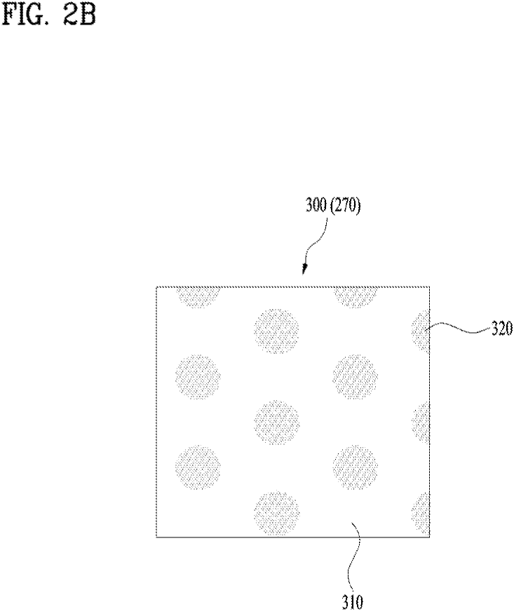

FIG. 1 is a cross-sectional diagram showing pixel regions of a display device using light emitting elements according to one embodiment of the present disclosure. FIG. 2A is a cross-sectional diagram showing a unit pixel region of a display device using light emitting elements according to one embodiment of the present disclosure. FIG. 2B is an enlarged diagram showing a display device using light emitting elements according to one embodiment of the present disclosure.

Referring to FIG. 1, in a display device 10, light emitting elements 200 that configure a multitude of pixels may be located in a manner of being arranged on a wiring substrate 100 equipped with a wiring electrode 110. In this case, a reflective layer 300 may be located among a multitude of the light emitting elements 200.

For example, the reflective layer 300 may fill a space between the light emitting elements 200. In this case, the reflective layer 300 may include reflective particles 320 (see FIG. 2B) dispersed in a transparent resin layer 310 (see FIG. 2B). This will be described in detail later.

In FIG. 1, the wiring electrode 110 is schematically illustrated. A multitude of the wiring electrodes 110 may be located on a wiring substrate 100 in a manner of being partitioned. Here, the wiring electrode 110 may include a data electrode (i.e., a pixel electrode) and a scan electrode (i.e., a common electrode).

Although not shown in the drawing, the wiring electrode 110 arranged on the wiring substrate 100 may be connected to a TFT layer provided with a Thin Film Transistor (TFT). The data electrode (i.e., the pixel electrode) may be connected to such a TFT layer. A detailed description thereof will be omitted.

In the exemplary embodiment, as illustrated, the reflective layer 300 may have a hang structure 301 between the neighboring light emitting elements 200. That is, a curved structure 301 formed concavely between the neighboring light emitting elements 200 and continuously connected may be formed on a top surface of the reflective layer 300.

In other words, a maximum height a of the light emitting element 200 may be different from a minimum height a′ of the reflective layer 300. For example, the minimum height a′ of the reflective layer 300 may be lower than the maximum height a of the light emitting element 200. In other words, the height a′ of the hang structure 301 may be higher than half of the height a of the light emitting element 200.

The hang structure 301 may be associated with a fabricating process of the reflective layer 300. For example, when the reflective layer 300 is formed using a jetting process in which material is applied using a nozzle and then cured, the hang structure 301 may be formed.

The light emitting element 200 may be disposed on the wiring substrate 100 in a manner of forming an individual pixel. For example, a single light emitting element 200 may be configured to form a single pixel. Since the reflective layer 300 is formed to surround at least the side of the single light emitting element 200 forming the individual pixel, light emitted from the light emitting element 200 may be emitted upward without being mixed with light emitted from another light emitting element 200 forming a neighboring pixel.

That is, since light is emitted in all directions from the light emitting element 200, the light emitted in a lateral direction from the individual light emitting element 200 may be reflected by the reflective layer 300 and then emitted upward from the display device 10.

Therefore, since the light emitted from the light emitting element 200 and traveling in a lateral direction is blocked by the reflective layer 300, it is possible to fundamentally prevent the occurrence of bright lines between the pixels in the display device 10.

Referring to FIG. 2A, for example, the light emitting element 200 forming the individual pixel may include a semiconductor structure including a multitude of semiconductor layers 210, 220, and 230 stacked to emit light of a first color, a second color, and a third color.

As a specific example, the light emitting element 200 may include a layered semiconductor light emitting element capable of emitting red, green, and blue light.

For example, such a layered light emitting device 200 may include a semiconductor structure including a first semiconductor layer 210 emitting red light, a second semiconductor layer 220 emitting blue light, and a third semiconductor layer 230 emitting green light.

Here, each of the first semiconductor layer 210, the second semiconductor layer 220, and the third semiconductor layer 230 may include semiconductor layers capable of emitting light of individual colors. For example, each of the first semiconductor layer 210, the second semiconductor layer 220, and the third semiconductor layer 230 may include an active layer capable of emitting light of each individual color. As another example, each of the first semiconductor layer 210, the second semiconductor layer 220, and the third semiconductor layer 230 may include an n-type semiconductor layer and a p-type semiconductor layer together with an active layer capable of emitting light of an individual color. This individual structure is omitted in FIG. 2A.

In addition, the light emitting element 200 may include a first electrode 250 and a second electrode 260 electrically connected to one side and the other side of the semiconductor structure, respectively. In FIG. 2A, the semiconductor structure and the electrical connection structure of the first electrode 250 and the second electrode 260 are schematically illustrated.

A support layer 240 may be located on the semiconductor structure. Here, the support layer 240 may include a growth substrate in which a semiconductor structure is grown or a transfer substrate in which the semiconductor structure is transferred and bonded. The support layer 240 may be transparent with respect to light emitted from the semiconductor structure. For example, the support layer 240 may include a sapphire substrate.

Meanwhile, extension pads 251 and 261 may be provided to the first electrode 250 and the second electrode 260 electrically connected to one side and the other side of the semiconductor structure, respectively. The sizes of the extension pads 251 and 261 may increase to be larger than the outer surface of the semiconductor structure.

The description of the light emitting element 200 as other light sources will be described in detail below.

Here, the reflective layer 300 may be located to surround lateral sides of the semiconductor structure including the first semiconductor layer 210, the second semiconductor layer 220, and the third semiconductor layer 230 of the light emitting element 200 at least.

In addition, the reflective layer 300 may be located to cover the first electrode 250 and the second electrode 260. In addition, for example, the reflective layer 300 may be located to cover the extension pads 251 and 261.

The reflective layer 300 may be located to further surround a lateral side of the support layer 240 of the light emitting element 200. For example, the reflective layer 300 may be located to surround all sides except the top side of the support layer 240 of the light emitting element.

Referring to FIG. 2B, the reflective layer 300 may include reflective particles 320 dispersed in the transparent resin layer 310.

In an exemplary embodiment, the refractive index of the reflective particles 320 may be different from the refractive index of the transparent resin layer 310.

The reflective particles 320 may include at least one of silicon, titanium, zirconium, or an oxide thereof, that is, silicon oxide (SiOx), titanium oxide (TiOx), and zirconium oxide (ZrOx).

Meanwhile, the transparent resin layer 310 may be formed of a resin material. For example, the transparent resin layer 310 may include at least one material of silicon, epoxy, and urethane.

The thickness of the reflective layer 300 may be set to have a reflectivity of 90% or more by the transparent resin layer 310 and the reflective particles 320.

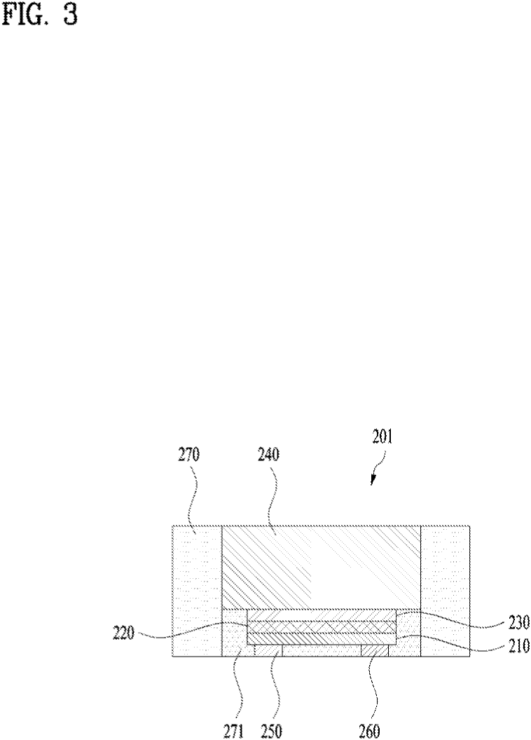

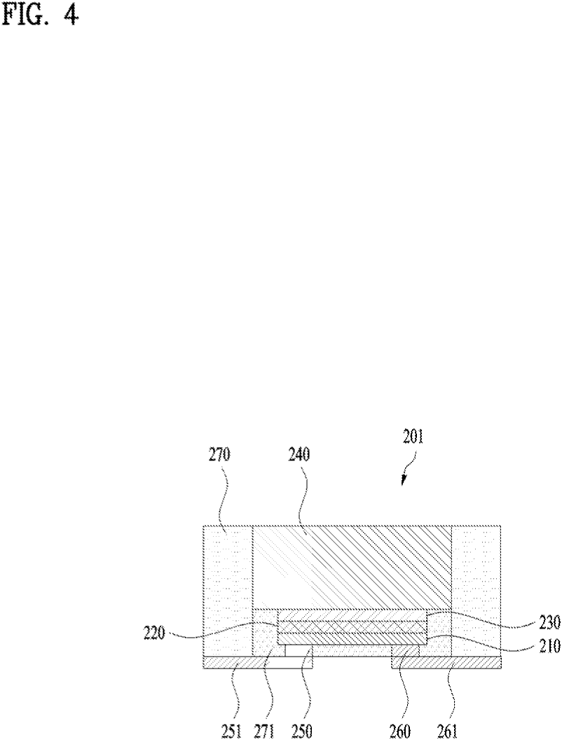

FIG. 3 is a cross-sectional diagram showing a light emitting element of a display device using light emitting elements according to one embodiment of the present disclosure. FIG. 4 is a diagram showing a modified example of the light emitting element of FIG. 3.

Referring to FIG. 3, a light emitting element 201 forming an individual pixel may include a semiconductor structure including a multitude of semiconductor layers 210, 220, and 230 stacked to emit lights of a first color, a second color, and a third color, respectively.

As a specific example, the light emitting element 201 may include a layered semiconductor light emitting element capable of emitting red, green, and blue lights.

For example, the layered light emitting element 201 may include a semiconductor structure including a first semiconductor layer 210 emitting red light, a second semiconductor layer 220 emitting blue light, and a third semiconductor layer 230 emitting green light.

Here, each of the first semiconductor layer 210, the second semiconductor layer 220, and the third semiconductor layer 230 may include a semiconductor layer capable of emitting light of an individual color. For example, each of the first semiconductor layer 210, the second semiconductor layer 220, and the third semiconductor layer 230 may include an active layer capable of emitting light of each individual color. As another example, each of the first semiconductor layer 210, the second semiconductor layer 220, and the third semiconductor layer 230 may include an n-type semiconductor layer and a p-type semiconductor layer together with an active layer capable of emitting light of each individual color.

In addition, the light emitting element 201 may include a first electrode 250 and a second electrode 260 electrically connected to one side and the other side of the semiconductor structure, respectively.

A support layer 240 may be located on the semiconductor structure. Here, the support layer 240 may include a growth substrate in which a semiconductor structure is grown or a transfer substrate in which the semiconductor structure is transferred and bonded. The size of the support layer 240 in a plane direction may be larger than that of the semiconductor structure.

Reflective layers 270 and 271 may be located on a lateral side of the semiconductor structure of the light emitting element 201.

Here, the reflective layers 270 and 271 may be located to surround the lateral side of the semiconductor structure including the first semiconductor layer 210, the second semiconductor layer 220, and the third semiconductor layer 230 at least.

In addition, the reflective layers 270 and 271 may be located to cover the first electrode 250 and the second electrode 260.

The reflective layers 270 and 271 may be located to further surround the lateral side of the support layer 240 of the light emitting element 201. For example, the reflective layer 300 may be located to surround all sides except the top side of the support layer 240 of the light emitting element.

In this case, as an exemplary embodiment, the reflective layer may include a first reflective layer 271 covering the lateral side and the bottom side of the semiconductor structure including the first semiconductor layer 210, the second semiconductor layer 220, and the third semiconductor layer 230 and the lateral sides of the first and second electrodes 250 and 260 and a second reflective layer 270 covering the lateral sides of the first reflective layer 271 and the support layer 240.

The reflective layers 270 and 271 may substantially extend the size of the light emitting element 201. The light emitting surface of the light emitting element 201 may be extended to a size including the reflective layers 270 and 271. That is, the light emitting surface having an area corresponding to the semiconductor structure may be extended to the size including the reflective layers 270 and 271.

Referring to FIG. 4, extension pads 251 and 261 respectively connected to the first electrode 250 and the second electrode 260 may be further provided.

The sizes of the extension pads 251 and 261 may be increased to be larger than the outer surface of the semiconductor structure. For example, the sizes of the extension pads 251 and 261 may extend to the outer surface of the reflective layer 270.

In this case, the top sides of the extension pads 251 and 261 may be in contact with the reflective layers 270 and 271. The extension pads 251 and 261 may further improve the reflectivity of the reflective layers 270 and 271. In addition, the extension pads 251 and 261 may form substantially external electrode pads of the light emitting element 201.

Other undescribed matters may be applied as described with reference to FIGS. 1 to 2B. For example, as described with reference to FIG. 2B, the reflective layers 270 and 271 may include reflective particles 320 dispersed in a transparent resin layer 310. That is, properties of the reflective layers 270 and 271 of the present embodiment may be substantially the same as those of the reflective layer 300 described above. In other words, the properties of the reflective layers 270 and 271 of the present embodiment may be the same as those of the reflective layer 300 described above, except for the property of having the hang structure 301. Thus, redundant descriptions will be omitted.

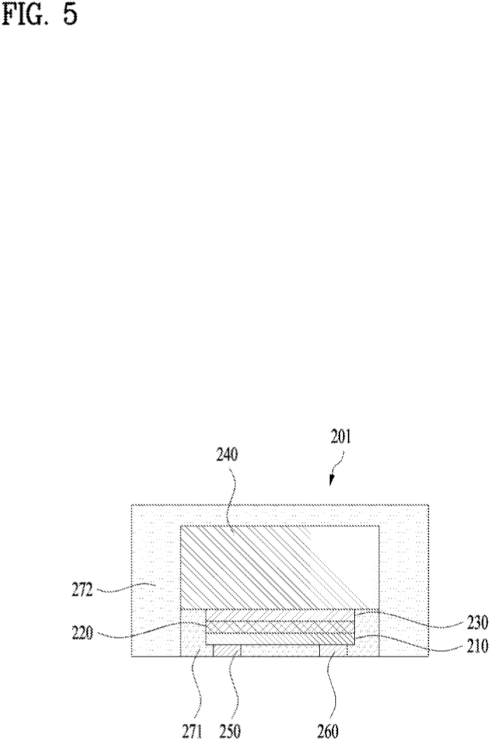

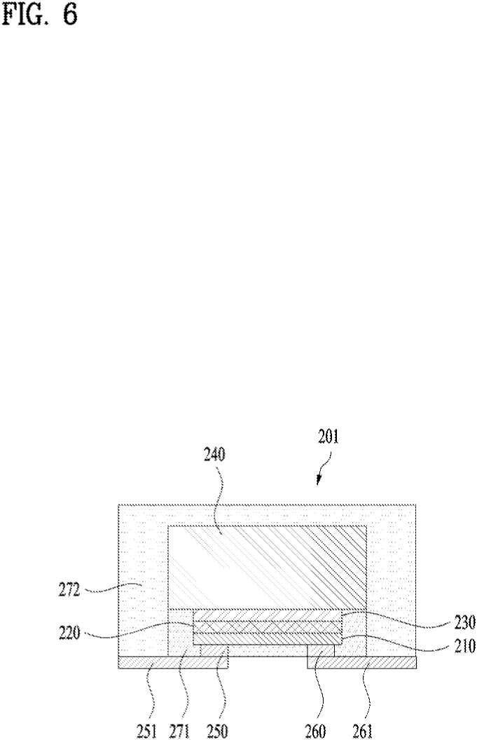

FIG. 5 is a cross-sectional diagram showing a light emitting element of a display device using light emitting elements according to another embodiment of the present disclosure. FIG. 6 is a diagram showing a modified example of the light emitting element of FIG. 5.

Referring to FIG. 5, a light emitting device 201 forming an individual pixel may include a semiconductor structure including a multitude of semiconductor layers 210, 220, and 230 stacked to emit lights of a first color, a second color, and a third color, respectively. Since the description of the semiconductor structure is the same as the description described with reference to FIG. 3, a redundant description will be omitted.

In addition, the light emitting element 201 may include a first electrode 250 and a second electrode 260 electrically connected to one side and the other side of the semiconductor structure, respectively.

A support layer 240 may be located on the semiconductor structure. Here, the support layer 240 may include a growth substrate in which a semiconductor structure is grown or a transfer substrate in which the semiconductor structure is transferred and bonded. The size of the support layer 240 in a plane direction may be larger than that of the semiconductor structure.

Reflective layers 271 and 272 may be located on a lateral side of the semiconductor structure of the light emitting element 201.

As an exemplary embodiment, the reflective layer may include a first reflective layer 271 covering lateral and bottom sides of the semiconductor structure including a first semiconductor layer 210, a second semiconductor layer 220, and a third semiconductor layer 230 and lateral sides of the first and second electrodes 250 and 260 and a second reflective layer 272 covering the first reflective layer 271 and lateral and top sides of the support layer 240.

As described above, the second reflective layer 272 may be located to surround the lateral and top sides of the support layer 240 of the light emitting element 201. The second reflective layer 272 may improve uniformity of light emitted from the light emitting element 201.

The reflective layers 271 and 272 may substantially extend the size of the light emitting element 201. A light emitting surface of the light emitting element 201 may be extended to a size including the reflective layers 271 and 272. That is, the light emitting surface having an area corresponding to the semiconductor structure may be extended to the size including the reflective layers 271 and 272.

Referring to FIG. 6, extension pads 251 and 261 respectively connected to the first electrode 250 and the second electrode 260 may be further provided.

The sizes of the extension pads 251 and 261 may increase to be larger than the outer surface of the semiconductor structure. For example, the sizes of the extension pads 251 and 261 may extend to the outer surface of the reflective layer 272.

In this case, top sides of the extension pads 251 and 261 may be in contact with the reflective layers 271 and 272. The extension pads 251 and 261 may further improve the reflectivity of the reflective layers 271 and 272. In addition, the extension pads 251 and 261 may form substantially external electrode pads of the light emitting element 201.

Other undescribed matters may be applied as described with reference to FIGS. 1 to 2B, 3 and 4. For example, as described with reference to FIG. 2B, the reflective layers 271 and 272 may include reflective particles 320 dispersed in a transparent resin layer 310. That is, properties of the reflective layers 271 and 272 of the present embodiment may be substantially the same as those of the reflective layer 300 described above. In other words, except for the property of having the hang structure 301, the properties of the reflective layers 271 and 272 of the present embodiment may be the same as those of the reflective layer 300 described above. Thus, redundant descriptions will be omitted.

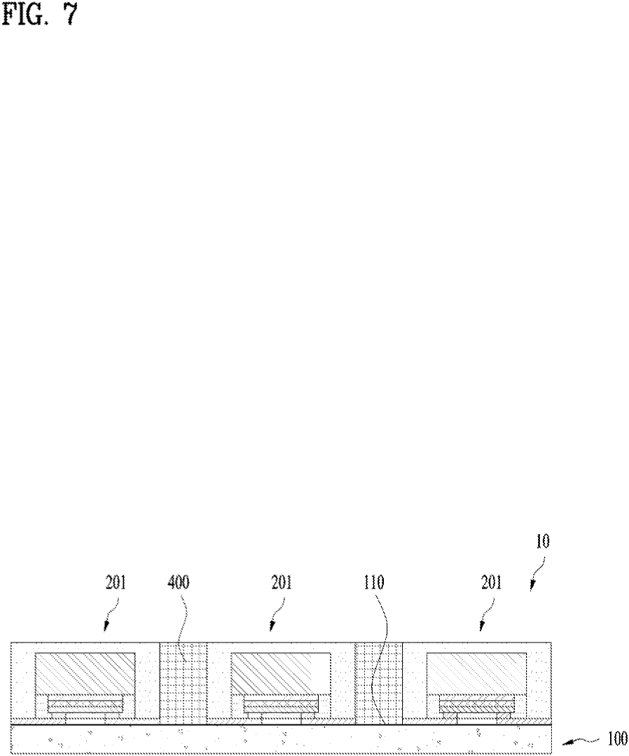

FIG. 7 is a cross-sectional diagram showing a light emitting element of a display device using light emitting elements according to another embodiment of the present disclosure.

Referring to FIG. 7, an embodiment of a display device 10 in which the light emitting element 201 according to the embodiment of FIG. 4 forms an individual pixel is illustrated.

That is, the light emitting element 201 according to the embodiment of FIG. 6 may be installed on a wiring substrate 100 to form an individual pixel. In this case, a gap layer 400 may fill a space between the individual light emitting elements 201.

In this way, the display device 10 may be implemented with a simple structure by using the light emitting element 201 having a structure extended by the reflective layers 270, 271, and 272.

In this case, a module display device 10 including a predetermined number of light emitting elements 201 may be implemented on the wiring substrate 100 having a predetermined size. The display device 10 having a desired size may be fabricated by combining the module display devices 10.

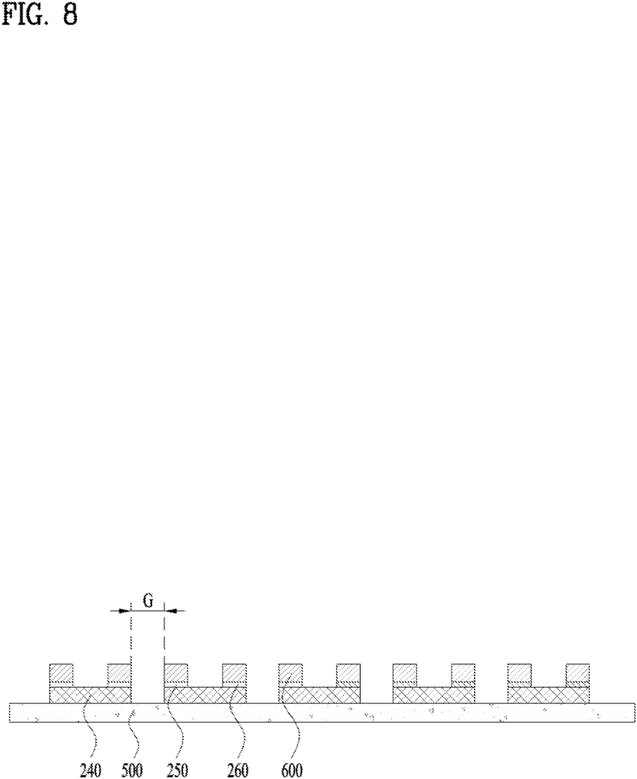

FIGS. 8 to 11 are schematic cross-sectional diagrams showing a process for fabricating a light emitting element of a display device using light emitting elements according to one embodiment of the present disclosure.

Referring to FIGS. 8 to 11, a process of fabricating a light emitting element according to the embodiment shown in FIG. 4 are shown step by step.

First, referring to FIG. 8, a support layer 240 may be located on a first substrate 500 to form a predetermined gap G. In FIG. 8, a semiconductor structure located on the support layer 240 is omitted.

While a first electrode 250 and a second electrode 260 are located on the support layer 240, a photoresist 600 may be formed on the first electrode 250 and the second electrode 260.

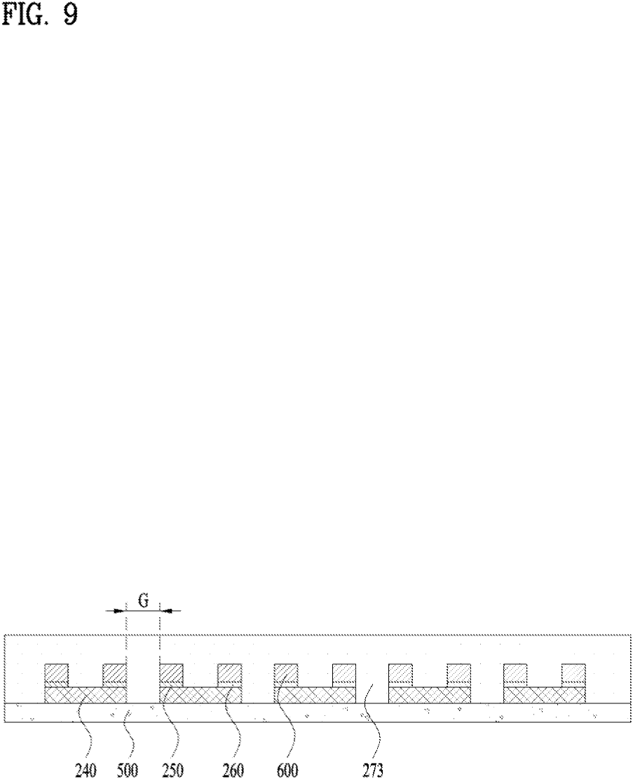

Referring to FIG. 9, a reflective layer 273 may be entirely formed in the state shown in FIG. 8. Here, the reflective layer 273 may have the same properties as the reflective layers 300, 270, 271, and 272 described above.

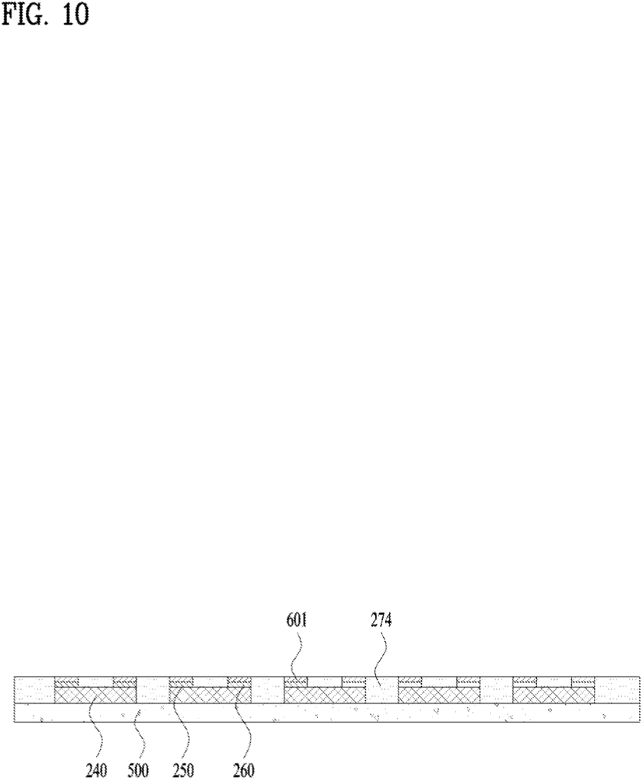

Next, referring to FIG. 10, the thickness of a top side of the structure shown FIG. 9 may be reduced. For example, as shown in FIG. 10 through a process such as wrapping the structure shown in FIG. 9, a photoresist 601 having a thinned thickness may be located on the first electrode 250 and the second electrode 260.

In this case, a reflective layer 274 having a thinned thickness may be located among the support layer 240, the first electrode 250, and the second electrode 260. That is, the reflective layer 274 may be located between the structures that will form the respective light emitting elements.

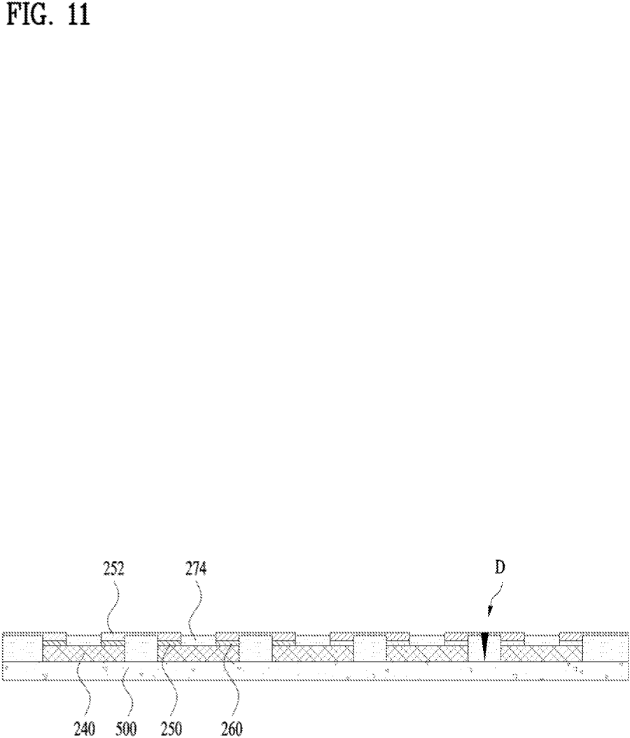

Referring to FIG. 11, a metal to form an extension pad 252 may be formed in a state in which the photoresist 601 is removed.

Thereafter, by dicing an area D dividing individual light emitting elements by such a method as laser, the light emitting element 201 having the structure shown in FIG. 4 may be fabricated.

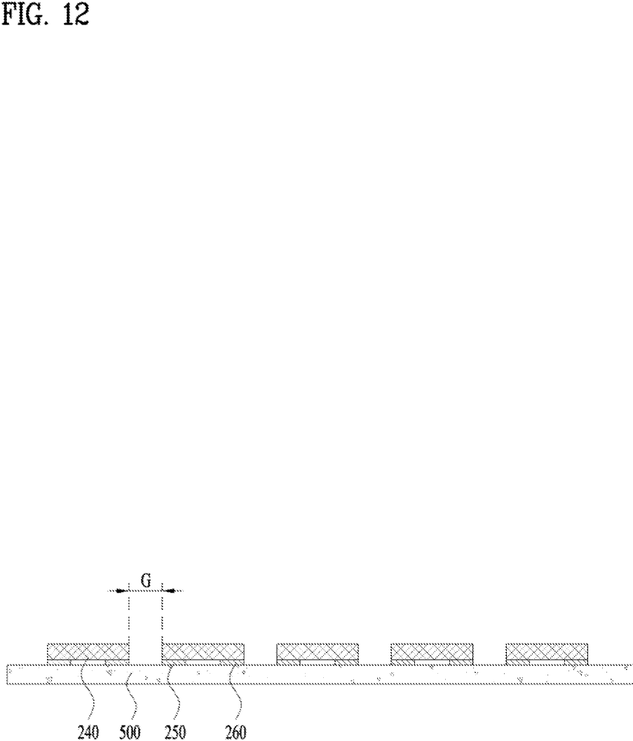

FIGS. 12 to 15 are schematic cross-sectional diagrams showing a process for fabricating a light emitting element of a display device using light emitting elements according to another embodiment of the present disclosure.

Referring to FIGS. 12 to 15, a process of fabricating a light emitting element shown in FIG. 6 is shown step by step.

First, referring to FIG. 12, a support layer 240 may be located on a first substrate 500 to form a predetermined interval G. In FIG. 8, a semiconductor structure located on the support layer 240 is omitted.

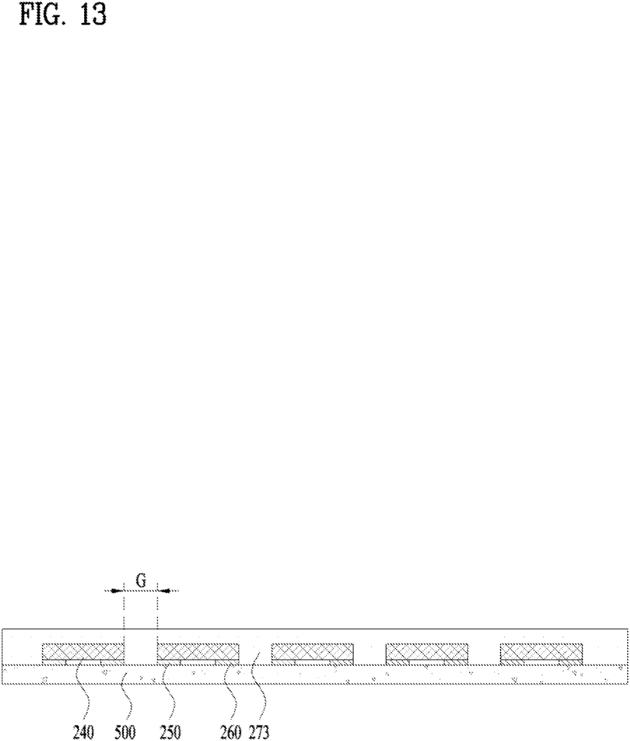

Referring to FIG. 13, a reflective layer 273 may be entirely formed in the state shown in FIG. 11. Here, the reflective layer 273 may have the same properties as the reflective layers 300, 270, 271, and 272 described above.

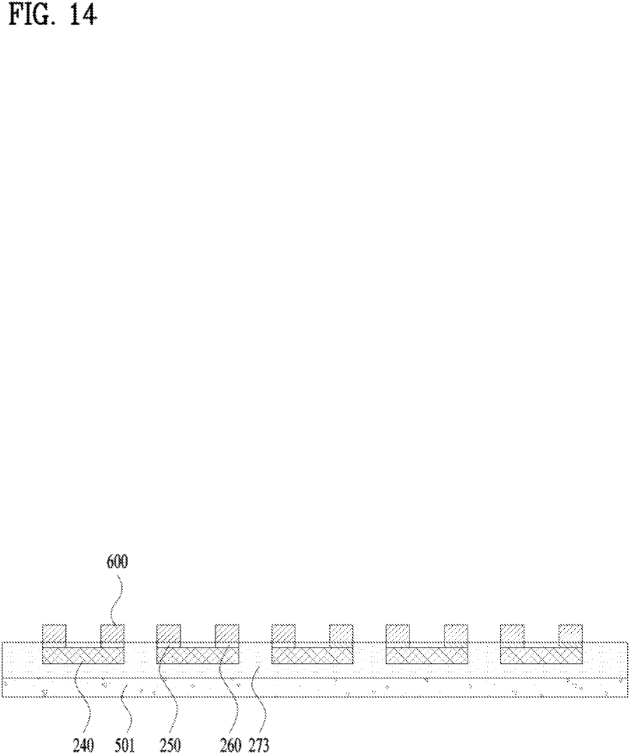

Referring to FIG. 14, the structure formed in FIG. 13 may be transferred to a second substrate 501.

In addition, while a first electrode 250 and a second electrode 260 are located on the support layer 240, a photoresist 600 may be formed on the first electrode 250 and the second electrode 260.

In this case, a reflective layer 273 may be located between the second substrate 501 and the support layer 240.

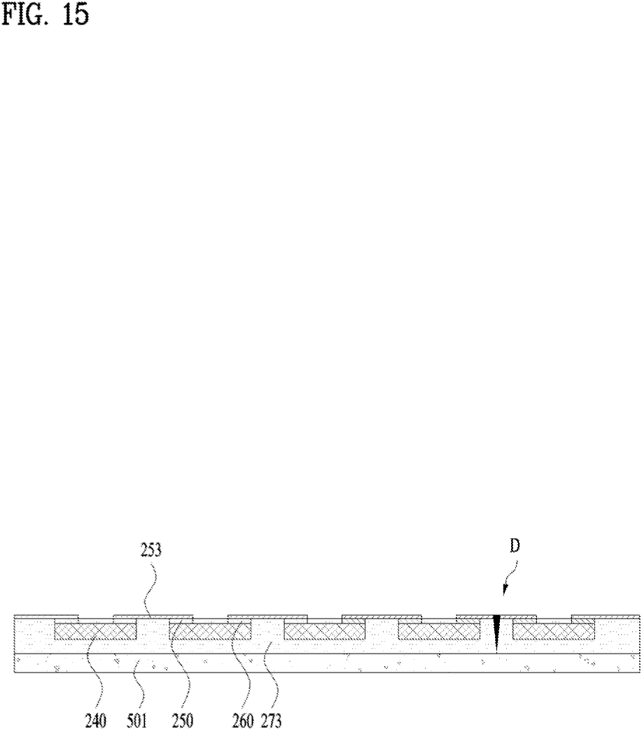

Subsequently, referring to FIG. 15, a metal to form an extension pad 252 may be formed in a state in which the photoresist 600 is removed.

Thereafter, when an area D dividing individual light emitting elements is diced by such a method as laser, a light emitting element 201 having the structure shown in FIG. 6 may be fabricated.

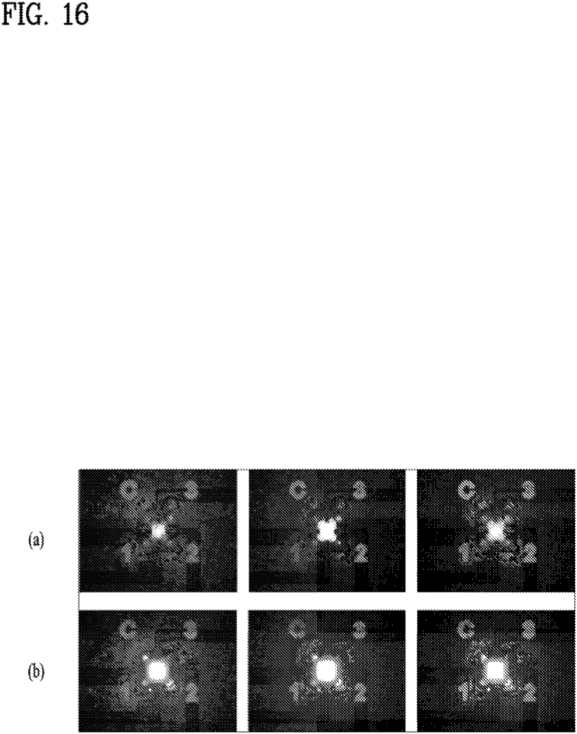

FIG. 16 is a diagram of pictures showing light emitting states by a light emitting element of a display device using light emitting elements according to another embodiment of the present disclosure.

FIG. 16 (a) illustrates a light emitting state by a light emitting element in a state in which the reflective layers 270, 271, and 272 are not provided as a comparative example.

In addition, FIG. 16 (b) illustrates a light emitting state by the light emitting element in a state in which the reflective layers 270, 271, and 272 are provided as an embodiment.

Comparing (a) and (b) of FIG. 16, it may be confirmed that the light emitting surface and the light emitting intensity are extended. That is, as described above, the size of the light emitting element 201 may be substantially extended by the reflective layers 270, 271, and 272. That is, the light emitting surface having an area corresponding to the semiconductor structure may be extended to a size including the reflective layers 270, 271, and 272.

According to an embodiment of the present disclosure, light traveling to a lateral side of a light emitting element is made to travel to a front side, thereby increasing light efficiency.

Moreover, it is possible to uniformize the viewing angles due to different light distribution properties among red, green, and blue.

In addition, when a display devices has a structure of mutually-connected modules, it is possible to improve the effect of bright line occurrence between the modules.

The above description is merely illustrative of the technical spirit of the present disclosure. It will be apparent to those skilled in the art that various modifications and variations can be made in the present disclosure without departing from the spirit and scope of the disclosure.

Therefore, the embodiments disclosed in the present disclosure are merely illustrative of the technical spirit of the present disclosure. The scope of the technical spirit of the present disclosure is not limited by these embodiments.

The scope of the present disclosure should be construed by the appended claims, and all technical ideas within the scope equivalent thereto should be construed as being within the scope of the present disclosure.

What is claimed is:

1. A layered light emitting element, comprising:
a semiconductor structure having a multitude of semiconductor layers stacked to emit lights of first to third colors, respectively;
first and second electrodes electrically connected to one side and the other side of the semiconductor layer on a first face of the semiconductor structure, respectively;
a support layer disposed on a second face of the semiconductor structure; and
a reflective layer disposed to surround a lateral side of the semiconductor structure at least.

2. The layered light emitting element of claim 1, wherein the reflective layer is disposed to further surround a lateral side of the support layer.

3. The layered light emitting element of claim 1, wherein the reflective layer has a predetermined thickness on the lateral side of the semiconductor structure.

4. The layered light emitting element of claim 1, the reflective layer comprising:
a transparent resin layer; and
reflective particles dispersed in the transparent resin layer.

5. The layered light emitting element of claim 4, wherein a refractive index of the reflective particles is different from a refractive index of the transparent resin layer.

6. The layered light emitting element of claim 4, wherein the reflective particles include at least one of silicon oxide, titanium oxide, or zirconium oxide.

7. The layered light emitting element of claim 4, wherein a thickness of the reflective layer is set to have a reflectivity of 90% or more by the transparent resin layer and the reflective particles.

8. The layered light emitting element of claim 4, wherein the transparent resin layer includes at least one material of silicon, epoxy, or urethane.

9. The layered light emitting element of claim 1, further comprising an extension pad connected to each of the first electrode and the second electrode.

10. The layered light emitting element of claim 9, wherein an outer side end of the extension pad is in contact with the reflective layer.

11. The layered light emitting element of claim 1, wherein the reflective layer is further located on a top side of the support layer.

12. A display device, comprising:
a wiring substrate;
a light emitting element disposed on the wiring substrate to form an individual pixel and having a semiconductor structure including a multitude of semiconductor layers stacked to emit lights of first to third colors, respectively; and
a reflective layer filling a space between the light emitting elements, the reflective layer comprising:
a transparent resin layer; and
particles dispersed in the transparent resin layer.

13. The display device of claim 12, wherein the reflective layer has a hang structure between neighboring light emitting elements.

14. The display device of claim 13, wherein a height of the hang structure is greater than a half of a height of the light emitting element.

15. The display device of claim 12, wherein a maximum height of the reflective layer corresponds to a greatest height of the light emitting element.

16. The display device of claim 12, wherein the reflective layer is located to surround a lateral side of the semiconductor structure at least in the individual light emitting element.

17. The display device of claim 12, wherein a refractive index of the reflective particles is different from a refractive index of the transparent resin layer.

18. The display device of claim 12, wherein the reflective particles include at least one of silicon oxide, titanium oxide, or zirconium oxide.

19. The display device of claim 12, wherein thickness of the reflective layer is set to have a reflectivity of 90% or more by the transparent resin layer and the reflective particles.

20. The display device of claim 12, wherein the transparent resin layer includes at least one material of silicon, epoxy, or urethane.
